(19) United States
(12) Patent Application Publication
(10) Pub. No.: US 2006/0029167 A1
(43) Pub. Date: Feb. 9, 2006

(54) Apparatus and method for sharing viterbi decoder in mobile communication system

(75) Inventors: Jin-Wook Han, Seoul (KR); Yong-Chan Kim, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/199,377

(22) Filed: Aug. 9, 2005

(30) Foreign Application Priority Data
Aug. 9, 2004 (KR) 10-2004-0062547

(51) Int. Cl. H04L 27/06; H03M 13/03

(52) U.S. Cl. 375/341; 714/795

(57) ABSTRACT

An apparatus and method are provided for decoding data of first and second control channels in a mobile communication system providing multi-media services including voice and data services. The apparatus includes an input section for selectively outputting data stored in first and second control channel input sections which store data of the first and second control channels, respectively, a viterbi decoder core block for outputting a decoding result by decoding the data output from the input section, an output section for storing the decoding result output from the viterbi decoder core block in one of first and second control channel output sections, and a controller for setting a second control channel delay flag, which is a signal for delaying data decoding for the second control channel, as “on” in order to perform data decoding for the first control channel if decoding start signals of the first and second control channels are simultaneously input.

### CROSS-REFERENCE TO RELATED APPLICATIONS

This application claims the benefit under 35 U.S.C. 119(a) of Korean Patent Application No. 10-2004-0062547 entitled “Apparatus And Method For Sharing Viterbi Decoder In Mobile Communication System” filed in the Korean Intellectual Property Office on Aug. 9, 2004, the entire disclosure of which is incorporated herein by reference.

### BACKGROUND OF THE INVENTION

1. Field of the Invention

The present invention relates to a mobile communication system for providing multi-media services including voice and data services. More particularly, the present invention relates to an apparatus and a method for sharing a decoder used for packet control channels.

2. Description of the Related Art

Conventional mobile communication systems, such as code division multiple access (CDMA) mobile communication systems, provide only voice services. However, as communication technologies have been developed in response to demands of users, mobile communication systems now provide data services in addition to the voice services. For instance, a high data rate (HDR) mobile communication system has been suggested for providing services with a high data rate. In particular, a 1×EV DV (Evolution Data and Voice) system has recently been spotlighted as a mobile system communication system that is capable of providing high-speed packet data services, as well as voice services.

The 1×EV-DV system employs control channels, such as a forward packet data control channel (F-PDCCH) and a forward grant channel (F-GCH), for providing such packet data services.

The F-PDCCH is a physical channel used for a terminal when the terminal transmits control information that is required for demodulating a forward packet data channel (F-PDCH). Thus, the F-PDCCH may carry a control message, which must necessarily be transmitted when a base station (BS) has packet data to be transferred to a receiving terminal. Accordingly, transmission duration and transmission instant of the F-PDCCH are identical to those of the F-PDCH.

The F-PDCCH has three transmission durations of 1.25 ms corresponding to 1 slot, 2.5 ms corresponding to 2 slots, and 5.0 ms corresponding to 4 slots. The transmission duration of the F-PDCCH per each transmission instant is selected by combining channel information and the buffer state of data to be transmitted using a scheduler of the base station.

If the terminal employs a reverse packet data channel (R-PDCH) radio configuration (RC) 7, the BS transmits data through the F-GCH per every 10 ms in order to grant the terminal to transmit at least one packet.

FIG. 1 is a block view illustrating a structure of an F-PDCCH transmitter.

Referring to FIG. 1, CRC bits are added to 13-bit forward packet data control information by means of an add 8 bit packet CRC (cyclic redundancy check) 10, and tail bits are added to 13-bit forward packet data control information by means of an add 8 bit encoder tail bits 12. An output of the add 8 bit encoder tail bits 12 is coded by means of a convolutional encoder 14 (k=9) using convolutional codes in order to correct an error caused by noise generated from a transmission channel. At this time, if the transmission durations corresponding to 1 slot, 2 slots, and 4 slots are represented as “n=1, 2, and 4”, the output of the add 8 bit encoder tail bits 12 coded by the convolutional encoder 14 is selectively symbol-repeated or symbol-punctured by means of a symbol repeater 16 and a symbol puncturer 18 according to the transmission durations.

The symbol-repeated or symbol-punctured data is converted into modulation symbols while being interleaved by means of a block interleaver 20, and mapped through a signal point mapping unit 22. The data is then multiplied by a channel gain by means of a channel gain controller 24 so that the data having a radio frequency (RF) band is transmitted through an antenna (not shown).

FIG. 2 is a block view illustrating a structure of an F-GCH transmitter.

Referring to FIG. 2, CRC bits are added to 14-bit grant information by means of an add 10 bit packet CRC 40, and tail bits are added to the 14-bit grant information by means of an add 8 bit encoder tail bits 42. An output of the add 8 bit encoder tail bits 42 is coded by means of a convolutional encoder 44 (k=9, R=¼) using convolutional codes in order to correct an error caused by noise generated from a transmission channel. In addition, an output of the convolutional encoder 44 is symbol-punctured by means of a symbol puncturer 46 and is interleaved by means of a block interleaver 48 so that the output of the convolutional encoder 44 is converted into a modulation symbol.

The modulation symbol is multiplied by scrambling bits by means of a scrambler 50 and mapped through a signal point mapping unit 52. The modulation symbol is then multiplied by a channel gain by means of a channel gain controller 54 so that data having a radio frequency (RF) band is transmitted through an antenna (not shown).

As shown in FIGS. 1 and 2, in order to demodulate data of the F-PDCCH and F-GCH using the convolution codes at receiving terminals thereof, a viterbi decoder is provided for the F-PDCCH and F-GCH, respectively. If a viterbi decoder is provided for each of the F-PDCCH and F-GCH, the amount of hardware and power consumption may increase.

Accordingly, a need exists for a system and method to provide a technique enabling the F-PDCCH and F-GCH to share one viterbi decoder.

### SUMMARY OF THE INVENTION

Accordingly, the present invention has been made to address the above-mentioned and other problems occurring in the prior art, and an object of the present invention is to provide an apparatus and method for sharing a viterbi decoder at receiving terminals of an F-PDCCH and an F-GCH.

Another object of the present invention is to provide a method for decoding received data of an F-PDCCH and an F-GCH through a shared viterbi decoder.

In order to accomplish these and other objects, according to one aspect of the present invention, an apparatus is provided for decoding data of first and second control channels in a mobile communication system providing multi-media services including voice and data services, the apparatus comprising an input section for selectively outputting data stored in first and second control channel input sections which store data of the first and second control channels, respectively, a viterbi decoder core block for outputting a decoding result by decoding the data output from the input section, an output section for storing the decoding result output from the viterbi decoder core block in one of first and second control channel output sections, and a controller for setting a second control channel delay flag, which is a signal for delaying data decoding for the second control channel, as “on” in order to perform data decoding for the first control channel if decoding start signals of the first and second control channels are simultaneously input thereto.

According to another aspect of the present invention, a method is provided for decoding data of first and second control channels by using a decoding device sharing a viterbi core block in a mobile communication system providing multi-media services including voice and data services, the method comprising the steps of checking decoding start signals of the first and second control channels, performing a decoding for the data of the first control channel while idling a decoding for the data of the second control channel if decoding start signals of the first and second control channels are simultaneously input, and continuously performing the decoding for the data of the first control channel while idling the decoding for the data of the second control channel if the decoding start signal for the second control channel is input while the data of the first control channel is being decoded.

According to an exemplary embodiment of the present invention, the method further comprises the steps of stopping the decoding for the data of the second control channel and performing the decoding for the data of the first control channel while idling the decoding for the data of the second control channel if the decoding start signal for the first control channel is input while the data of the second control channel is being decoded, determining if there is an idle state set for the data decoding of the second control channel when the decoding for the data of the first control channel has been completed, and performing the decoding for the data of the second control channel if the idle state is set for the data decoding of the second control channel.

### BRIEF DESCRIPTION OF THE DRAWINGS

The above and other exemplary objects, features and advantages of the embodiments of the present invention will become more apparent from the following detailed description taken in conjunction with the accompanying drawings, in which:

FIG. 1 is a schematic view illustrating a structure of an F-PDCCH transmitter;

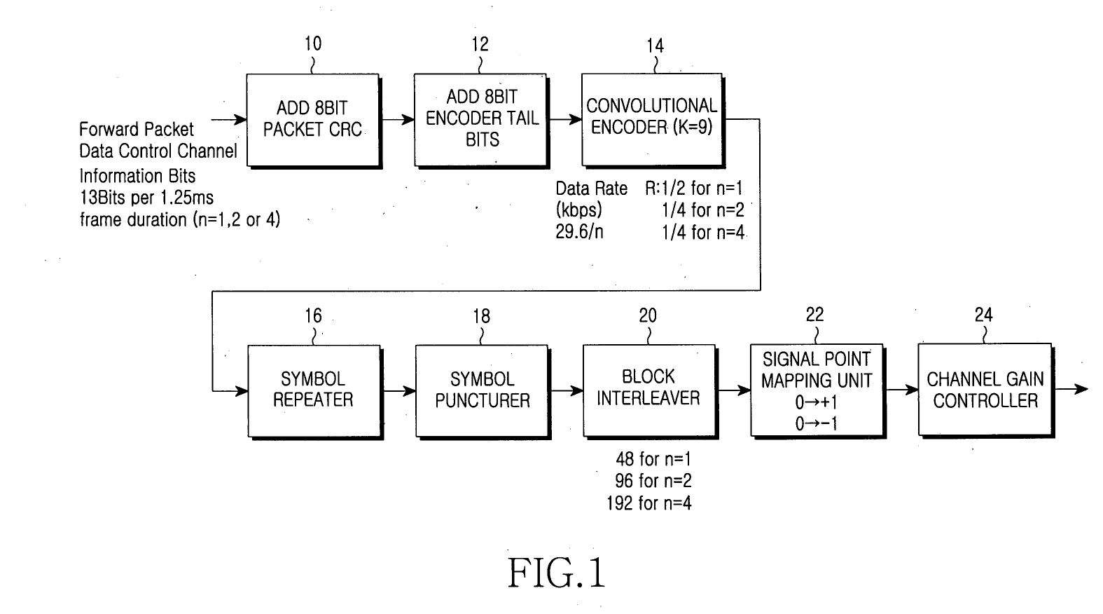

FIG. 2 is a schematic view illustrating a structure of an F-GCH transmitter;

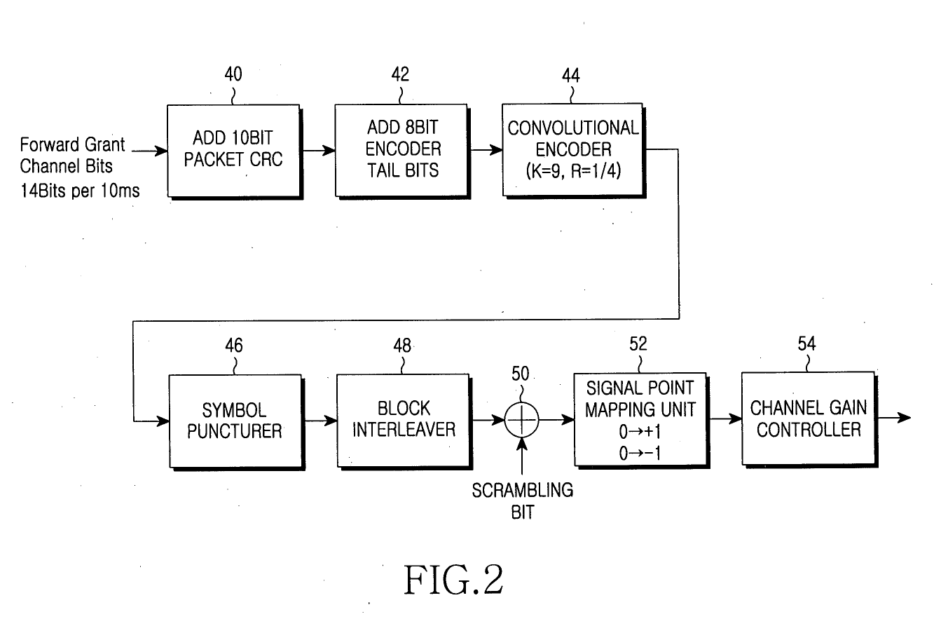

FIG. 3 is a block diagram illustrating a structure of a decoder according to an embodiment of the present invention;

FIG. 4 is a view illustrating an exemplary decoding scheme when PDCCH and GCH decoding start signals are simultaneously input according to an embodiment of the present invention;

FIG. 5 is a view illustrating an exemplary decoding scheme when a GCH decoding start signal is input while a PDCCH decoding is being performed according to an embodiment of the present invention;

FIG. 6 is a view illustrating an exemplary decoding scheme when a PDCCH decoding start signal is input while a GCH decoding is being performed according to an embodiment of the present invention; and

FIG. 7 is a flowchart illustrating an exemplary operational procedure of a shared viterbi core controller according to an embodiment of the present invention.

Throughout the drawings, like reference numerals will be understood to refer to like parts, components and structures.

### DETAILED DESCRIPTION OF THE EXEMPLARY EMBODIMENTS

Hereinafter, a number of exemplary embodiments of the present invention will be described with reference to the accompanying drawings. Wherever possible, the same reference numbers will be used throughout the drawings to refer to the same or like parts. In addition, a detailed description of functions and configurations incorporated herein that are well known to those skilled in the art will be omitted for clarity and conciseness. The terms used in the following description are defined by taking functions thereof into consideration, such that the terms may vary depending on customs or intentions of the user. Thus, definitions of terms are preferably determined based on the whole content of the present invention.

According to an embodiment of the present invention, an F-PDCCH and an F-GCH are designed such that they share a core of a viterbi decoder at receiving terminals thereof. In addition, in order to prevent interference of decoding time between the F-PDCCH and the F-GCH caused by the shared decoder, the decoding time is controlled when the decoding is performed in the F-PDCCH and the F-GCH.

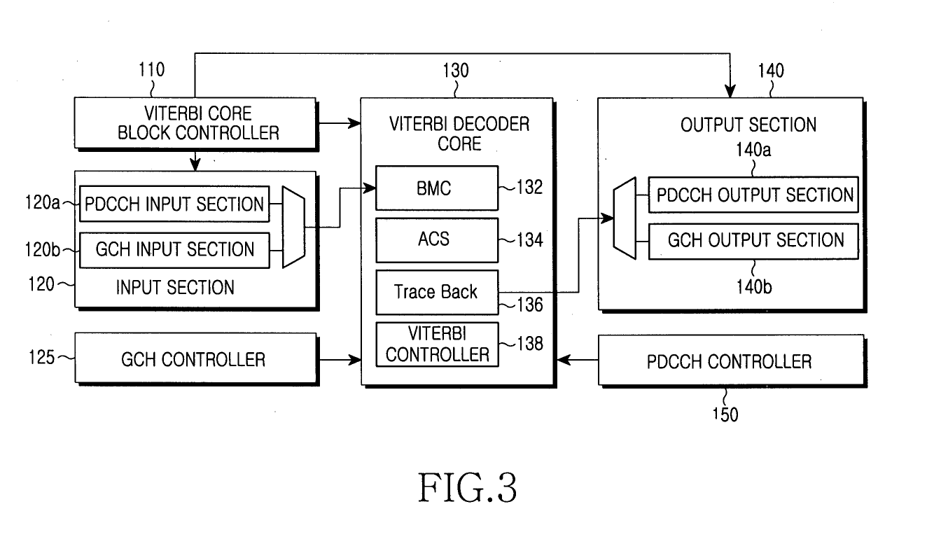

FIG. 3 is a block diagram illustrating a structure of a decoder shared by the F-PDCCH and F-GCH according to an embodiment of the present invention.

Referring to FIG. 3, the decoder shared by the F-PDCCH and the F-GCH mainly comprises a viterbi core controller 110, an input section 120, a GCH controller 125, a viterbi decoder core block 130, an output section 140, and a PDCCH controller 150.

The viterbi decoder core block 130 comprises a branch metric calculator (BMC) 132 for calculating a branch metric value for each lattice-type branch, an add compare select (ACS) block 134 for selecting survivor paths by calculating a path metric value according to the branch metric value, a trace back block 136 for performing a decoding by tracing back the survivor paths, and a viterbi controller 138 for controlling the BMC 132, the ACS 134, and the trace back block 136.

The viterbi core controller 110 controls the input section 120, which selects and stores one of a PDCCH input section 120a and a GCH input section 120b according to the decoding start signals, the viterbi decoder core block 130, and the output section 140. The output section 140 stores the decoding result for a signal output from the viterbi decoder core block 130 in one of a PDCCH output section 140a and a GCH output section 140b.

In an exemplary implementation of the present invention, upon receiving the decoding start signal of the F-PDCCH, the viterbi core controller 110 outputs received data of the F-PDCCH to the BMC 132 through the PDCCH input section 120a. In addition, upon receiving the decoding start signal of the F-GCH, the viterbi core controller 110 outputs received data of the F-GCH to the BMC 132 through the GCH input section 120b. When the decoding for the F-PDCCH has been finished, the viterbi core controller 110 outputs an output signal of the trace back block 136 through the PDCCH output section 140a. In addition, when the decoding for the F-GCH has been finished, the viterbi core controller 110 outputs an output signal of the trace back block 136 through the GCH output section 140b.

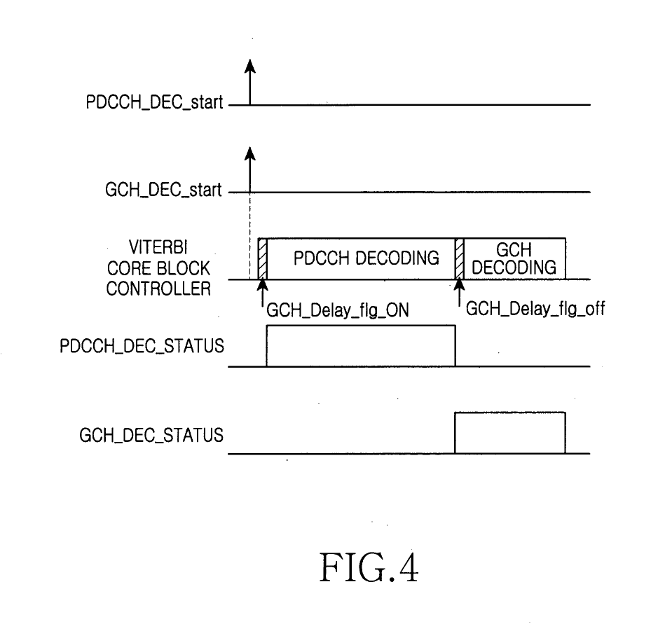

The viterbi decoder core block 130 performs the decoding for the PDCCH and GCH under the time-control of the viterbi core controller 110. A time-control scheme of the viterbi core controller 110 for decoding data of the PDCCH and GCH will be described in greater detail below with reference to FIGS. 4 to 6.

The GCH controller 125 controls the GCH decoding while interfacing with the viterbi decoder core block 130, and the PDCCH controller 150 controls the PDCCH decoding while interfacing with the viterbi decoder core block 130. In addition, the viterbi core controller 110 performs time-control such that the viterbi decoder core block 130 can be shared when decoding the GCH or the PDCCH.

The shared viterbi decoder can perform at least three exemplary types of operations according to the decoding start signals input thereto. The three types of operations of the viterbi decoder may be represented as respectively occurring when PDCCH and GCH decoding start signals are simultaneously input, when the GCH decoding start signal is input while performing the PDCCH decoding, and when the PDCCH decoding start signal is input while performing the GCH decoding. The shared viterbi decoder performs the time-control according to the operation type thereof, thereby decoding the PDCCH or GCH.

Data of the F-PDCCH is received with a time interval of 1.25 ms, and maximum decoding time for the received data of the F-PDCCH including process time for blind rate detection is about 0.1 ms. Data of the F-GCH is received with a time interval of 10 ms, and maximum decoding time for the received data of the F-GCH is about 0.03 ms, which is shorter than that of the F-PDCCH. Thus, the F-PDCCH decoding is performed prior to the F-GCH decoding because the F-PDCCH does not have a sufficient time interval.

Hereinafter, an exemplary decoding operation of a decoder according to a decoding start signal will be described in detail with reference to FIGS. 4 to 7.

An IDLE state signifies that the viterbi core controller 110 waits for the F-PDCCH decoding start signal (PDCCH_DEC_start) or the F-GCH decoding start signal (GCH_DEC_start). If the PDCCH_DEC_start is “1”, PDCCH_DEC_STATUS, which represents that the F-PDCCH decoding is being performed, is shifted to “1”. If the GCH_DEC_start is “1”, GCH_DEC_STATUS, which represents that the F-GCH decoding is being performed, is shifted to “1”. The GCH_Delay_Flg is a flag for introducing the F-GCH decoding after the F-PDCCH decoding has been completed. The GCH_DEC_Core_Reset is a signal for initializing registers of the BMC 132, ACS 134, and trace back (TB) 136 in order to perform the F_PDCCH decoding while the F-GCH decoding is being performed.

FIG. 4 is a view illustrating a decoding scheme when PDCCH and GCH decoding start signals are simultaneously input according to an embodiment of the present invention.

Referring to FIG. 4, in the idle state, the PDCCH_DEC_start and GCH_DEC_start are simultaneously shifted to “1”. In this case, the viterbi core controller 110 sets the GCH_Delay_Flg as “on” and shifts the PDCCH_DEC_start to “1” for performing the F-PDCCH decoding. When the F-PDCCH decoding has been completed, the viterbi core controller 110 shifts the PDCCH_DEC_start to “0” and sets the GCH_Delay_Flg as “off” for performing the F-GCH decoding. At this time, the GCH_DEC_start is shifted to “1”.

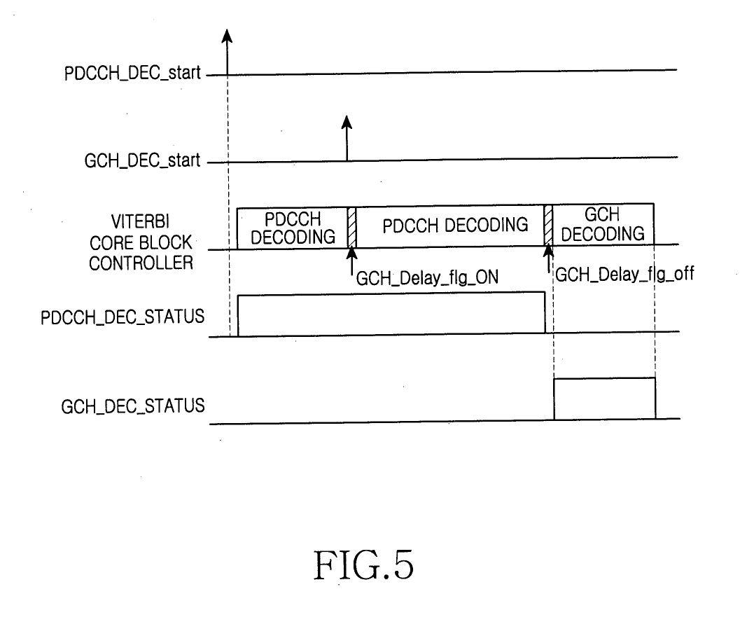

FIG. 5 is a view illustrating a decoding scheme when the GCH decoding start signal is input while the PDCCH decoding is being performed according to an embodiment of the present invention.

Referring to FIG. 5, the PDCCH_DEC_start is first shifted to “1” so that the GCH_DEC_start is shifted to “1” while the F-PDCCH decoding is being performed. In this case, the viterbi core controller 110 shifts the PDCCH_DEC_start to “1” from the time point of receiving the PDCCH_DEC_start, thereby performing the PDCCH decoding. If the GCH_DEC_start is input while the PDCCH decoding is being performed, the viterbi core controller 110 sets the GCH_Delay_Flg as “on” from the time point of receiving the GCH_DEC_start and continuously performs the F-PDCCH decoding. Thus, the PDCCH_DEC_start can be maintained at “1”. When the F-PDCCH decoding has been completed, the viterbi core controller 110 shifts the PDCCH_DEC_start to “0” and sets the GCH_Delay_Flg as “off” for performing the GCH decoding. When the GCH decoding starts, GCH_DEC_start is shifted to “1”.

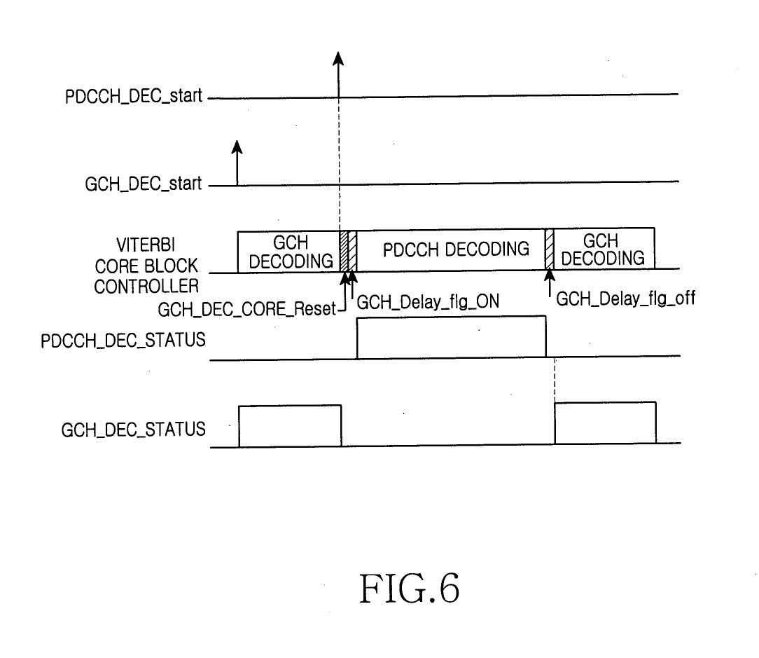

FIG. 6 is a view illustrating a decoding scheme when the PDCCH decoding start signal is input while the GCH decoding is being performed according to an embodiment of the present invention.

Referring to FIG. 6, the GCH_DEC_start is first input with “1”, so the viterbi core controller 110 performs the GCH decoding by shifting the GCH_DEC_start to “1”. If the PDCCH_DEC_start becomes “1” while the GCH decoding is being performed, the viterbi core controller 110 sets the GCH_DEC_CORE_Reset as “1” and shifts the GCH_DEC-start to “0” after stopping the GCH decoding. Since the GCH decoding is temporarily stopped, the viterbi core controller 110 sets the GCH_Delay_Flg as “on” and shifts the PDCCH_DEC_start to “1”, thereby performing the PDCCH decoding. When the PDCCH decoding has been completed, the viterbi core controller 110 shifts the PDCCH_DEC_start to “0” and sets the GCH_Delay_Flg as “off”, thereby restarting the GCH decoding. At this time, the GCH_DEC_start is again shifted to “1”.

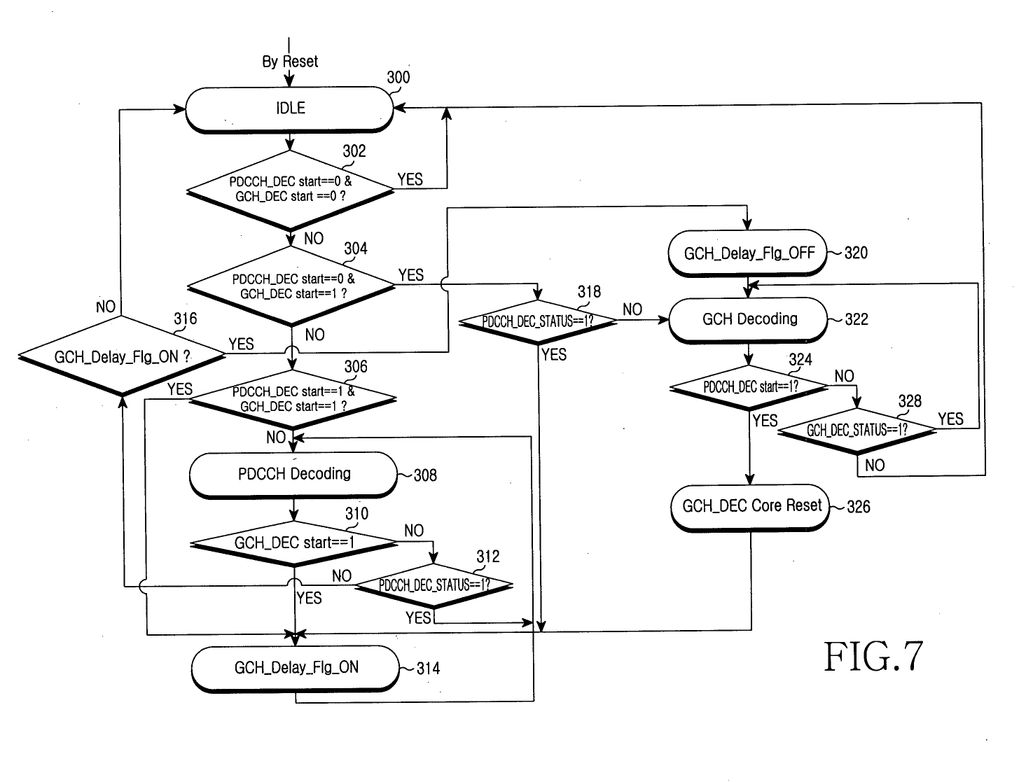

FIG. 7 is a flowchart illustrating an operational procedure of a shared viterbi core controller according to an embodiment of the present invention.

Referring to FIG. 7, step 300 is an idle state waiting for the decoding start signal of the decoder.

In step 302, if the PDCCH_DEC_start and the GCH_DEC_start are “0”, the procedure returns to step 300. Otherwise, step 304 is performed. In step 304, the viterbi core controller determines if “PDCCH_DEC_start=0 and GCH_DEC_start=1”. If it is determined in step 304 that the PDCCH_DEC_start is “0” and the GCH_DEC_start is shifted to “1”, step 318 is performed. Otherwise, step 306 is performed.

In step 318, the viterbi core controller 110 determines if the PDCCH_DEC_STATUS is “1”. If it is determined in step 318 that the PDCCH_DEC_STATUS is “1”, step 314 is performed. Otherwise, step 322 is performed.

In step 306, the viterbi core controller determines if the PDCCH_DEC_start and the GCH_DEC_start are “1”. If it is determined in step 306 that the PDCCH_DEC_start and the GCH_DEC_start are “1”, which corresponds to the case shown in FIG. 4, step 314 is performed in order to set the GCH_Delay_Flg as “on”. However, if it is determined in step 306 that the PDCCH_DEC_start or the GCH_DEC_start is not “1”, step 308 is carried out to perform the PDCCH decoding. Then, step 310 is performed. In step 310, the viterbi core controller 110 determines if the GCH_DEC_start is “1”. If it is determined in step 310 that the GCH_DEC_start is “1”, which corresponds to the case shown in FIG. 5, step 314 is performed. However, if it is determined in step 310 that the GCH_DEC_start is not “1”, step 312 is performed. In step 312, the viterbi core controller 110 determines if the PDCCH_DEC_STATUS is “1”. If it is determined in step 312 that the PDCCH_DEC_STATUS is “1”, step 308 is performed. Otherwise, step 316 is performed. In step 316, the viterbi core controller 110 checks the state of the GCH_Delay_Flg. If the state of the GCH_Delay_Flg is “off”, the procedure returns to step 300. In addition, if the state of the GCH_Delay_Flg is “on”, step 320 is performed.

In step 320, the viterbi core controller 110 sets the GCH_Delay_Flg as “off” and performs the GCH decoding in step 322. While the GCH decoding is being performed, step 324 is carried out in order to determine if the PDCCH_DEC_start is “1”. If the PDCCH_DEC_start is “1”, which corresponds to the case shown in FIG. 6, the viterbi core controller 110 stops the GCH decoding in step 326 and performs step 314. However, if it is determined in step 324 that the PDCCH_DEC_start is not “1”, step 328 is performed in order to determine if the GCH_DEC_STATUS is “1”. If it is determined in step 328 that the GCH_DEC_STATUS is “1”, the procedure returns to step 322. Otherwise, the procedure returns to step 300.

As described above, according to embodiments of the present invention, the logic of the decoder can be shared for the F-PDCCH and the F-GCH in the 1×EV-DV system, so that the gate count is reduced. As the gate count is reduced, power consumption and chip size, which are important factors in the RF environment, can be minimized so that the cost for the chip can be reduced.

While the invention has been shown and described with reference to certain exemplary embodiments thereof, it will be understood by those skilled in the art that various changes in form and detail may be made therein without departing from the spirit and scope of the invention as defined by the appended claims.

What is claimed is:

1. An apparatus for decoding data of first and second control channels in a mobile communication system providing multi-media services including voice and data services, the apparatus comprising:
an input section for selectively outputting data stored in first and second control channel input sections, wherein the first and second control channel input sections are configured to store data of first and second control channels, respectively;
a viterbi decoder core block for outputting a decoding result by decoding the data output from the input section;
an output section for storing the decoding result output from the viterbi decoder core block in one of first and second control channel output sections; and
a controller for setting a second control channel delay flag, wherein the second control channel delay flag comprises a signal for delaying data decoding for the second control channel, as “on” in order to perform data decoding for the first control channel if decoding start signals of the first and second control channels are simultaneously input.

2. The apparatus as claimed in claim 1, wherein the viterbi core block comprises:
a branch metric calculator (BMC) for calculating a branch metric value for each of a lattice-type branch formed according to the data output from the input section;
an add compare select (ACS) block for selecting survivor paths by calculating a path metric value according to the branch metric value;
a trace back block for performing a decoding by tracing back the survivor paths; and
a viterbi controller for controlling at least one of the BMC, the ACS, and the trace back block.

3. The apparatus as claimed in claim 1, wherein the input section is configured to output the data of the first control channel stored in the first control channel input section to the viterbi core block if the controller determines decoding is to occur for the first control channel, and is further configured to output the data of the second control channel stored in the second control channel input section to the viterbi core block if the controller determines decoding is to occur for the second control channel.

4. The apparatus as claimed in claim 1, wherein the output section is configured to store the decoding result output from the viterbi core block in the first control channel output section if the controller determines the decoding for the first control channel, and is further configured to store the decoding result output from the viterbi core block in the second control channel output section if the controller determines the decoding for the second control channel.

5. The apparatus as claimed in claim 1, wherein the controller comprises:
a first control channel controller for controlling a decoding operation of the viterbi decoder core block when decoding the data of the first control channel;
a second control channel controller for controlling a decoding operation of the viterbi decoder core block when decoding the data of the second control channel; and
a viterbi core controller for controlling at least one of the input section, the output section, and the viterbi core block for allowing the input section to select the data of the first control channel or the second control channel according to the decoding start signals of the first and second control channels, for allowing the output section to store the decoding result, and for determining the decoding of the viterbi core block.

6. The apparatus as claimed in claim 1, wherein the controller is configured to set the second control channel delay flag as “on” if a decoding start signal for the second control channel is input thereto while the data of the first control channel is being decoded and allow the data of the first control channel to be continuously decoded.

7. The apparatus as claimed in claim 5, wherein the controller is configured to stop the decoding for the data of the second control channel and set the second control channel delay flag as “on” in order to perform the decoding for the data of the first control channel when a decoding start signal for the first control channel is input into the controller while the data of the second control channel is being decoded.

8. The apparatus as claimed in claim 1, wherein the controller is configured to determine if the second control channel delay flag is an “on” state when the decoding for the data of the first control channel has been completed and if the second control channel delay flag is the “on” state, setting the second control channel delay flag as “off” in order to perform the decoding for the data of the second control channel.

9. The apparatus as claimed in claim 6, wherein the controller is configured to determine if the second control channel delay flag is an “on” state when the decoding for the data of the first control channel has been completed and if the second control channel delay flag is the “on” state, setting the second control channel delay flag as “off” in order to perform the decoding for the data of the second control channel.

10. The apparatus as claimed in claim 7, wherein the controller is configured to determine if the second control channel delay flag is an “on” state when the decoding for the data of the first control channel has been completed and if the second control channel delay flag is the “on” state, setting the second control channel delay flag as “off” in order to perform the decoding for the data of the second control channel.

11. The apparatus as claimed in claim 1, wherein the first control channel comprises a forward packet data control channel (F-PDCCH) for transmitting control information required for demodulating a forward packet data channel (F-PDCH), and the second control channel comprises a forward grant channel (F-GCH) for granting a terminal to transmit at least one packet when the terminal employs a reverse packet data channel (R-PDCH) radio configuration (RC) 7.

12. A method for decoding data of first and second control channels by using a decoding device sharing a viterbi core block in a mobile communication system providing multi-media services including voice and data services, the method comprising the steps of:
checking decoding start signals of first and second control channels;
performing a decoding for data of the first control channel and setting an idle state for idling a decoding for data of the second control channel if the decoding start signals of the first and second control channels are simultaneously input;
continuously performing a decoding for data of the first control channel and setting an idle state for idling a decoding for data of the second control channel if the decoding start signal for the second control channel is input while the data of the first control channel is being decoded;
stopping a decoding for data of the second control channel and performing a decoding for data of the first control channel and setting an idle state for idling a decoding for data of the second control channel if the decoding start signal for the first control channel is input while the data of the second control channel is being decoded;
determining if an idle state is set for data decoding of the second control channel when the decoding for the data of the first control channel has been completed; and
performing decoding for the data of the second control channel if an idle state is set for the data decoding of the second control channel.

13. The method as claimed in claim 12, further comprising the steps of:
storing the data of the first and second control channels in first and second control channel input sections, respectively; and
storing decoding results for the data of the first and second control channels in first and second control channel output sections, respectively.

14. The method as claimed in claim 12, wherein the first control channel comprises a forward packet data control channel (F-PDCCH) for transmitting control information required for demodulating a forward packet data channel (F-PDCH), and the second control channel comprises a forward grant channel (F-GCH) for granting a terminal to transmit at least one packet when the terminal employs a reverse packet data channel (R-PDCH) radio configuration (RC) 7.
